(19) United States
(12) Patent Application Publication
(10) Pub. No.: US 2023/0100228 A1
(43) Pub. Date: Mar. 30, 2023

(54) PHYSICAL AND ELECTRICAL PROTOCOL TRANSLATION CHIPLETS

(71) Applicant: Intel Corporation, Santa Clara, CA (US)

(72) Inventors: Gerald PASDAST, San Jose, CA (US); Sathya Narasimman TIAGARAJ, San Jose, CA (US); Adel A. ELSHERBINI, Tempe, AZ (US); Tanay KARNIK, Portland, OR (US); Dileep KURIAN, Bangalore (IN); Julien SEBOT, Portland, OR (US)

(21) Appl. No.: 17/485,217

(22) Filed: Sep. 24, 2021

(51) Int. Cl. H01L 25/065; H01L 23/00; H01L 23/48

(52) U.S. Cl. CPC H01L 25/0652; H01L 24/73; H01L 24/14; H01L 23/481; H01L 25/0657; H01L 2224/73104; H01L 2224/14177; H01L 2225/06513

(57) ABSTRACT

Embodiments disclosed herein include dies and die modules. In an embodiment, a die comprises a substrate with a first surface and a second surface opposite from the first surface. In an embodiment the substrate comprises a semiconductor material. In an embodiment, first bumps with a first pitch are on the first surface of the substrate. In an embodiment, a first layer surrounds the first bumps, where the first layer comprises a dielectric material. In an embodiment, second bumps with a second pitch are on the substrate. In an embodiment, the second pitch is greater than the first pitch. In an embodiment, a second layer surrounds the second bumps, where the second layer comprises a dielectric material.

### TECHNICAL FIELD

Embodiments of the present disclosure relate to electronic packages, and more particularly to electronic packages with pitch and communication protocol translation chiplets.

### BACKGROUND

In multi-chip modules, it is often difficult to integrate existing IP blocks since not all devices include backwards compatibility. That is, it is challenging to connect chiplets that are manufactured at a first node with a previous generation integrated circuit (IC) that was designed on a second (different) node that has physically different bump pitch and bandwidth requirements. This can also occur at the system on a chip (SOC) level where newer IPs (e.g., network on chip) may not be compatible with older IPs (e.g., processing core). When converting the design to fine granularity disaggregation, each IP block becomes a microchiplet and this problem turns into a protocol/physical pitch translation problem.

Previous solutions involve manufacturing the dies again with a different bump pitch. For the SOC level, it involves synthesizing a soft IP that is responsible for the protocol translation. However, these solutions involve addition effort in floor planning, turnaround time for design, and turnaround time to market for different electrical chiplets that talk to each other.

### BRIEF DESCRIPTION OF THE DRAWINGS

FIG. 1A is a cross-sectional illustration of a protocol pitch translation die (PPTD) that has first bumps with a first pitch on a top surface and second bumps with a second pitch on a bottom surface, in accordance with an embodiment.

FIG. 1B is a cross-sectional illustration of a PPTD that has first bumps with a first pitch on a top surface and second bumps with a second pitch on the top surface, in accordance with an embodiment.

FIG. 2A is a cross-sectional illustration of a die module with a PPTD that couples a first die with first bumps to a second die with second bumps in a 3D architecture, in accordance with an embodiment.

FIG. 2B is a cross-sectional illustration of a die module with a PPTD that couples a first die with first bumps to a second die with second bumps in a 3D architecture, in accordance with an embodiment.

FIG. 2C is a cross-sectional illustration of a die module with a pair of PPTDs that couple dies to a base die in a 3D architecture, in accordance with an embodiment.

FIG. 3 is a cross-sectional illustration of a hybrid bonding interconnect (HBI) interface that may be used to coupled dies together, in accordance with an embodiment.

FIG. 4 is a cross-sectional illustration of a die module with a PPTD that couples together a first die and a second die with different bump pitches in a 2.5D architecture, in accordance with an embodiment.

FIG. 5 is a cross-sectional illustration of a die module with a PPTD that includes solder interconnects with a first die and an HBI interface with a second die, in accordance with an embodiment.

FIG. 6 is a cross-sectional illustration of an electronic package with a die module that comprises a PPTD to connect a first die with a first bump pitch to a second die with a second bump pitch, in accordance with an embodiment.

FIG. 7 is a cross-sectional illustration of an electronic system with a plurality of PPTDs for connecting dies with different bumps pitches together, in accordance with an embodiment.

FIG. 8 is a schematic of a computing device built in accordance with an embodiment.

### EMBODIMENTS OF THE PRESENT DISCLOSURE

Described herein are electronic packages with pitch and communication protocol translation chiplets, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, as more computing architectures being adopting multi-chip module architectures, difficulties of chiplet interconnectivity are becoming more apparent. Accordingly, embodiments disclosed herein include the use of protocol pitch translation dies (PPTDs) that provide physical pitch translation and/or protocol translation. With respect to physical pitch translation, the PPTD may include a first set of bumps with a first pitch and a second set of bumps with a second pitch. The pitch translation may be configured for 3D architectures or 2.5D architectures, as will be described in greater detail below. With respect to protocol translations, embodiments include PPTDs that are active devices. That is, active circuitry on the PPTDs can provided to provide functionality to account for signal count mismatches (e.g., through serialization and/or deserialization), signal frequency mismatches, and/or signal voltage mismatches.

Accordingly, the PPTDs in accordance to embodiments disclosed herein allow for two dies with different communication protocols and/or physical bump pitch differences to be communicatively coupled together. This allows for the re-use of existing chiplet architectures without needing to redesign the chiplet. Additionally, embodiments allow for backward compatibility to previous IP blocks and/or SOC architectures. Embodiments also allow for translation to standard die-to-die (D2D) interfaces and/or other generic or standardized IO interfaces. In yet another embodiment, assembly risk is reduced since uneven bump pitches can be avoided.

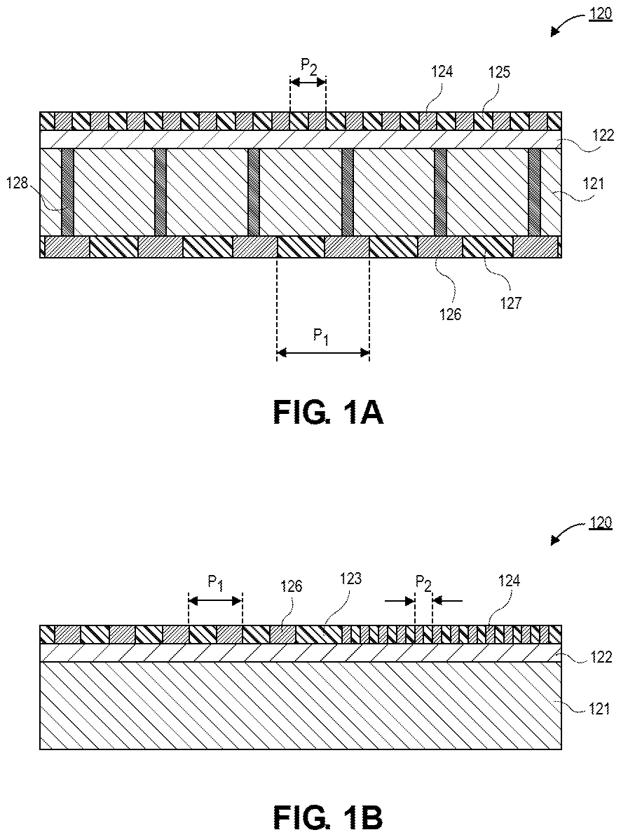

Referring now to FIG. 1A, a cross-sectional illustration of a die 120 is shown, in accordance with an embodiment. In an embodiment, the die 120 may be a PPTD. That is, the die 120 may be used to make pitch and/or protocol translations between two dies with different bump pitch and/or communication protocols. In an embodiment, the die 120 may comprise a substrate 121. The substrate 121 may be a semiconductor substrate. For example, the substrate 121 may comprise silicon.

In an embodiment the die 120 may comprise a top surface and a bottom surface. First bumps 126 may be provided on the bottom surface. In an embodiment, the first bumps 126 may have a first pitch P₁. The first bumps 126 may be a conductive material, such as copper. The first bumps 126 may also be surrounded by a dielectric layer 127. The dielectric layer 127 may comprise a dielectric suitable for hybrid bonding, such as a layer comprising silicon and oxygen (e.g., SiO_{X}). In an embodiment, the bottom surface of the first bumps 126 may be substantially coplanar with the bottom surface of the dielectric layer 127. As used herein, “substantially coplanar” may refer to two surfaces that are within 5 μm of being coplanar with each other. In a particular embodiment, the first bumps 126 may be slightly recessed from the dielectric layer 127 (e.g., by 100 nm or less, or by 10 nm or less) as is common in hybrid bonding architectures.

In an embodiment, second bumps 124 may be provided on the top surface of the substrate 121. The second bumps 124 may have a second pitch P₂. The second pitch P₂ may be smaller than the first pitch P₁. In a particular embodiment, the second pitch P₂ may be approximately 20 μm or smaller, or approximately 10 μm or smaller. The second bumps 124 may be a conductive material, such as copper. The second bumps 124 may also be surrounded by a dielectric layer 125. The dielectric layer 125 may comprise a dielectric suitable for hybrid bonding, such as a layer comprising silicon and oxygen (e.g., SiO_{X}). In an embodiment, the top surface of the second bumps 124 may be substantially coplanar with the top surface of the dielectric layer 125. In a particular embodiment, the second bumps 124 may be slightly recessed from the dielectric layer 125 (e.g., by 100 nm or less, or by 10 nm or less) as is common in hybrid bonding architectures.

As will be described in greater detail below, the top surface/bottom surface bump architecture allows for 3D die module architectures. That is, a first die can be provided over the top surface of the die 120 (and coupled to the second bumps 124), and a second die can be provided below the bottom surface of the die 120 (and coupled to the first bumps 126). Alternatively, the die 120 can be flipped so that the larger pitched first bumps 126 are on the top surface and the smaller pitched second bumps 124 are on the bottom surface.

In an embodiment, the die 120 may further comprise through substrate vias (TSVs) 128. The TSVs 128 may pass through a thickness of the substrate 121. As shown, the TSVs 128 do not pass through the entire thickness of the substrate 121. Instead, the TSVs 128 end at an active circuitry 122 of the substrate 121. However, it is to be appreciated that the TSVs 128 may pass entirely through the substrate 121 in some embodiments. The TSVs 128 may provide electrical coupling between the first bumps 126 and the second bumps 124. That is, the TSVs 128 may provide a vertical connection through the substrate 121. However, it is to be appreciated that additional circuitry and/or conductive routing may be provided between the TSVs 128 and the second bumps 124. Pitch translation between the first pitch P₁ and the second pitch P₂ is provided through the TSVs 128 and the layer of active circuitry 122.

In an embodiment, the die 120 may comprise active circuitry (e.g., transistors and the like) in a layer of active circuitry 122. In an embodiment, the active circuitry 122 provides communication protocol translation. In one embodiment, a number of first bumps 126 may be different than a number of second bumps 124. As such, the active circuitry 122 may be configured to provide serialization and/or deserialization in order to accommodate the different number of first bumps 126 and second bumps 124. In another embodiment, the active circuitry 122 provides signal frequency modulation. For example, a 100 GHz frequency may be converted 200 GHz frequency. In yet another embodiment, the active circuitry 122 may provide voltage modulation of signals that pass between the first bumps 126 and the second bumps 124.

Referring now to FIG. 1B, a cross-sectional illustration of a die 120 is shown, in accordance with an additional embodiment. In an embodiment, the die 120 may be a PPTD. In an embodiment, the die 120 may comprise a substrate 121. The substrate 121 may be a semiconductor substrate, such as silicon. In an embodiment, the substrate 121 has a top surface and a bottom surface.

In an embodiment, first bumps 126 are provided on the top surface of the substrate 121. The first bumps 126 may be conductive material, such as copper. In an embodiment, the first bumps 126 may have a first pitch P₁. Second bumps 124 may also be on the top surface of the substrate 121. The second bumps 124 may be conductive material, such as copper. In an embodiment, the second bumps 124 have a second pitch P₂. The second pitch P₂ may be smaller than the first pitch P₁. For example, the second pitch P₂ may be approximately 20 μm or smaller, or approximately 10 μm or smaller. In an embodiment, a dielectric layer 123 may surround the first bumps 126 and the second bumps 124. The dielectric layer 123 may be a material suitable for hybrid bonding interconnect interfaces, such as a layer comprising silicon and oxygen (e.g., SiO_{X}).

Providing both the first bumps 126 and the second bumps 124 on the top surface allows for the integration of dies in a 2.5D architecture. In such an embodiment, a first die may be over the first bumps 126 and a second die may be over the second bumps 124. The die 120 provides electrical coupling between the first die and the second die. Such an architecture may be referred to as being 2.5D since the first die and the second die are within the same X-Y plane, and the connection between the two dies is made by the die 120 in a different X-Y plane. This is opposed to a 3D architecture where the first die and the second die are provided in different X-Y planes.

In an embodiment, the first bumps 126 may be coupled to the second bumps 124 through conductive traces (not shown) that are provided in the substrate 121. In some embodiments, the conductive traces may be provided in the layer with active circuitry 122 or in the substrate 121. In an embodiment, the active circuitry 122 may include transistors and the like to provide communication protocol translations. In one embodiment, a number of first bumps 126 may be different than a number of second bumps 124. As such, the active circuitry 122 may be configured to provide serialization and/or deserialization in order to accommodate the different number of first bumps 126 and second bumps 124. In another embodiment, the active circuitry 122 provides signal frequency modulation. For example, a 100 GHz frequency may be converted 200 GHz frequency. In yet another embodiment, the active circuitry 122 may provide voltage modulation of signals that pass between the first bumps 126 and the second bumps 124.

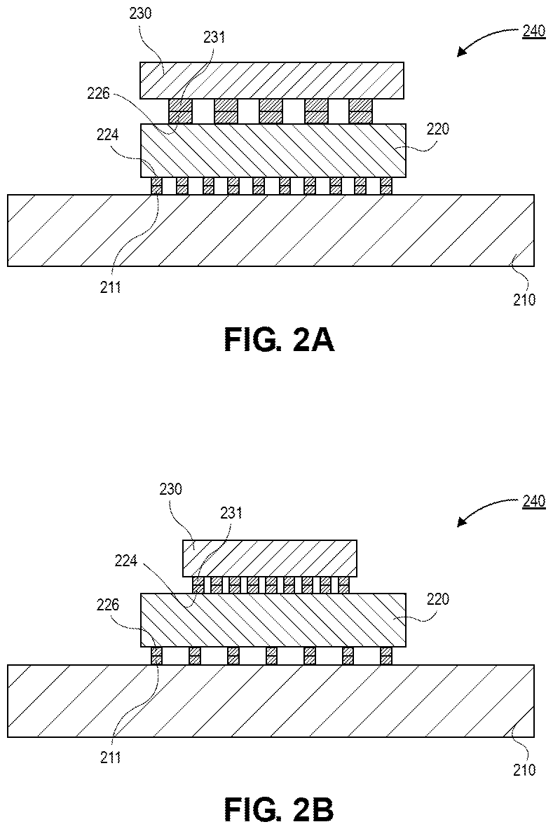

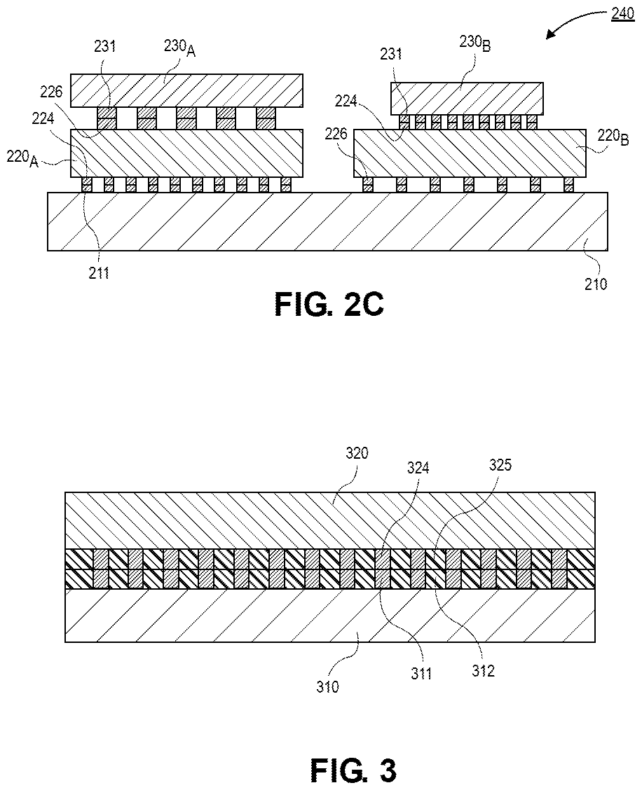

Referring now to FIG. 2A, a cross-sectional illustration of a die module 240 is shown, in accordance with an embodiment. In an embodiment, the die module 240 comprises a first die 210 and a second die 230. In an embodiment, the first die 210 has bumps 211 with a first pitch, and the second die 230 has bumps 231 with a second pitch that is different than the first pitch. Accordingly, a physical pitch translation is needed. In an embodiment, a third die 220 may provide the physical pitch translation. For example, the third die 220 may have first bumps 226 that have the second pitch and second bumps 224 that have the first pitch.

In an embodiment, the dies in the die module 240 may be bonded together using hybrid bonding interconnect interfaces. That is, the bumps 211 may be interdiffusion bonded to the second bumps 224, and the bumps 231 may be interdiffusion bonded to the first bumps 226. While not shown, embodiments also include dielectric layers around the bumps 211, 224, 226, and 231 that are also bonded together. A more detailed description of the hybrid bonding and methods of implementing hybrid bonding are described in greater detail below.

In an embodiment, the third die 220 may be substantially similar to the die 120 described in greater detail above with respect to FIG. 1A. That is, the third die 220 may be a PPTD. As shown, the third die 220 provides the physical pitch translation necessary for the first die 210 to be coupled to the second die 230. In addition to the physical pitch translation, the third die 220 may provide communication protocol translation as well. For example, the third die 220 may include active circuitry (not shown) that provides the communication protocol translation. In one embodiment, a number of first bumps 126 may be different than a number of second bumps 124. As such, the active circuitry may be configured to provide serialization and/or deserialization in order to accommodate the different number of first bumps 126 and second bumps 124. In another embodiment, the active circuitry provides signal frequency modulation. In yet another embodiment, the active circuitry may provide voltage modulation of signals that pass between the first bumps 126 and the second bumps 124.

Referring now to FIG. 2B, a cross-sectional illustration of a die module 240 is shown, in accordance with an additional embodiment. The die module 240 in FIG. 2B may be substantially similar to the die module 240 in FIG. 2A, with the exception of the orientation of the third die 220. Instead of having the first bumps 226 on the top surface and the second bumps 224 on the bottom surface (as shown in FIG. 2A), the third die 220 is flipped so that the second bumps 224 are on the top surface and the first bumps 226 are on the bottom surface. As illustrated, the second bumps 224 may be bonded to the bumps 231 of the second die 230, and the first bumps 226 may be bonded to the bumps 211 of the first die 210. Such an embodiment, may be useful when the first die 210 (i.e., a base die) is at a lower process node than the second die 230 (e.g., a chiplet).

Despite the change in orientation, the third die 220 may have similar functionality as the third die 220 described with respect to FIG. 2A. As shown, physical pitch translation is provided. Additionally, the third die 220 can provide communication protocol translation. For example, active circuitry on the third die 220 can provide serialization/deserialization, frequency modulation, and/or voltage modulation.

Referring now to FIG. 2C, a cross-sectional illustration of a die module 240 is shown, in accordance with an additional embodiment. In an embodiment, the die module 240 may comprise a first die 210 and a pair of second dies 230A and 230B. The second die 230A may be coupled to the first die 210 by a third die 220A, and the second die 230B may be coupled to the first die 210 by a third die 220B. That is, die modules 240 may include a plurality of third dies 220 that serve as pitch and/or communication protocol translation dies.

In an embodiment, the second die 230A may have bumps 231 that are at a pitch greater than the bumps 211 of the first die 210. As such, the third die 220A is oriented so that the first bumps 226 are on the top surface, and the second bumps 224 are on the bottom surface. That is, the first bumps 226 are bonded to the bumps 231, and the second bumps 224 are bonded to the bumps 211.

In an embodiment, the second die 230B may have bumps 231 that are at a pitch that is smaller than the bumps 211 of the first die 210. As such, the third die 220B is oriented so that the first bumps 226 are on the bottom surface, and the second bumps 224 are on the top surface. That is, the first bumps 226 are bonded to the bumps 211, and the second bumps 224 are bonded to the bumps 231.

In an embodiment, each of the dies 210, 220, and 230 may be coupled to each other with hybrid bonding interconnects. However, FIG. 2C only illustrates the conductive bumps of the hybrid bonding. It is to be appreciated that dielectric layers may also be provided so that there is a dielectric bond and a conductor bond for each of the interfaces. A more detailed description of the hybrid bonding is provided below with respect to FIG. 3.

Referring now to FIG. 3, a cross-sectional illustration of a hybrid bonding interconnect interface is shown, in accordance with an embodiment. As shown, a first die 310 is coupled to a second die 320 by the hybrid interface. The first die 310 may be a base die and the second die 320 may be a PPTD. A third die on the other side of the second die 320 is omitted in order to be able to zoom in on the hybrid interface.

In an embodiment, the first die 310 may comprise first bumps 311. The first bumps 311 may be a conductive material, such as copper. In an embodiment, the first bumps 311 may be surrounded by a first dielectric layer 312. The first dielectric layer 312 may be any suitable dielectric material for hybrid bonding interfaces. In one embodiment, the first dielectric layer 312 comprises silicon and oxygen (e.g., SiO_{X}).

In an embodiment, the second die 320 may comprise second bumps 324. The second bumps 324 may be a conductive material, such as copper. In an embodiment, the second bumps 324 may be surrounded by a second dielectric layer 325. The second dielectric layer 325 may be any suitable dielectric material for hybrid bonding interfaces. In one embodiment, the second dielectric layer 325 comprises silicon and oxygen (e.g., SiO_{X}).

In an embodiment, the first dielectric layer 312 may be bonded to the second dielectric layer 325, and the first bumps 311 are bonded to the second bumps 324. That is, there are two different material compositions that are bonded together (i.e., dielectric-to-dielectric and conductor-to-conductor). In an embodiment, the bonding process may utilize different temperatures to make the different bonds. The dielectric layers 312 and 325 may be bonded together at a low temperature, and the bumps 311 and 324 may be bonded to each other at a relatively higher temperature. The bumps 311 and 324 may be bonded together by an interdiffusion bonding process. While a distinct interface between the first bumps 311 and the second bumps 324 is shown, in some embodiments the interface may not be present. That is, the first bumps 311 and the second bumps 324 may substantially merge together and appear as a single continuous block between the first die 310 and the second die 320.

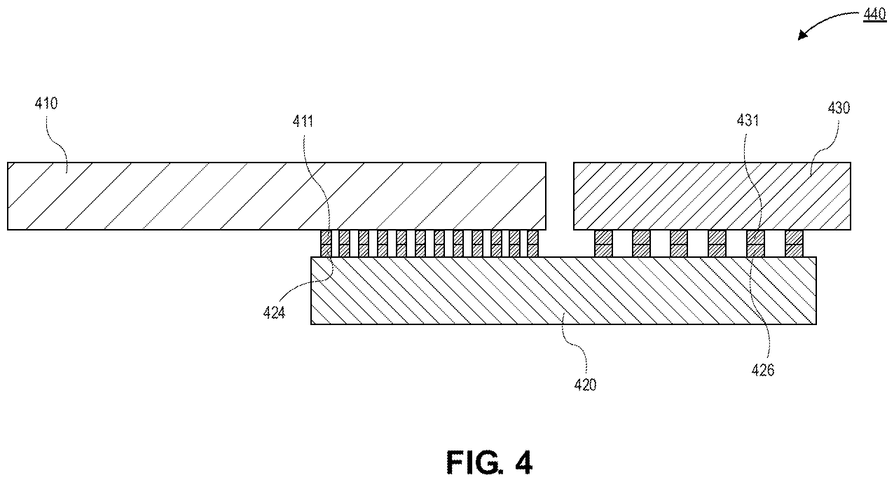

Referring now to FIG. 4, a cross-sectional illustration of a die module 440 is shown, in accordance with an additional embodiment. In an embodiment, the die module 440 may comprise a first die 410 and a second die 430. The first die 410 and the second die 430 may be positioned adjacent to each other. In an embodiment, the first die 410 and the second die 430 may be coupled together by a third die 420.

In an embodiment, the third die 420 may be a PPTD. In contrast to the PPTDs described above, the third die 420 includes first bumps 426 and second bumps 424 that are on the same surface of the third die 420. The first bumps 426 may have a first pitch, and the second bumps 424 may have a second pitch that is smaller than the first pitch. As such, a pitch translation between bumps 431 on the second die 430 and bumps 411 on the first die 410 can be provided. Furthermore, it is to be appreciated that the connection between the first die 410 and the third die 420 may be referred to as a 2.5D architecture since the first die 410 and the second die 430 are in a first X-Y plane, and the third die 420 that connects the two dies 410 and 430 is in a second X-Y plane below the first X-Y plane. While shown without dielectric layers around the bumps 411, 424, 431, and 426, it is to be appreciated that dielectric layers may be present to provide hybrid bonding between the various dies in the die module 440.

In addition to providing physical bump pitch translation, embodiments may also include a third die 420 that provides communication protocol translation. For example, active circuitry on the second die 420 can provide serialization/deserialization, frequency modulation, and/or voltage modulation. In an embodiment, the third die 420 may be substantially similar to the die 120 described in greater detail above with respect to FIG. 1B.

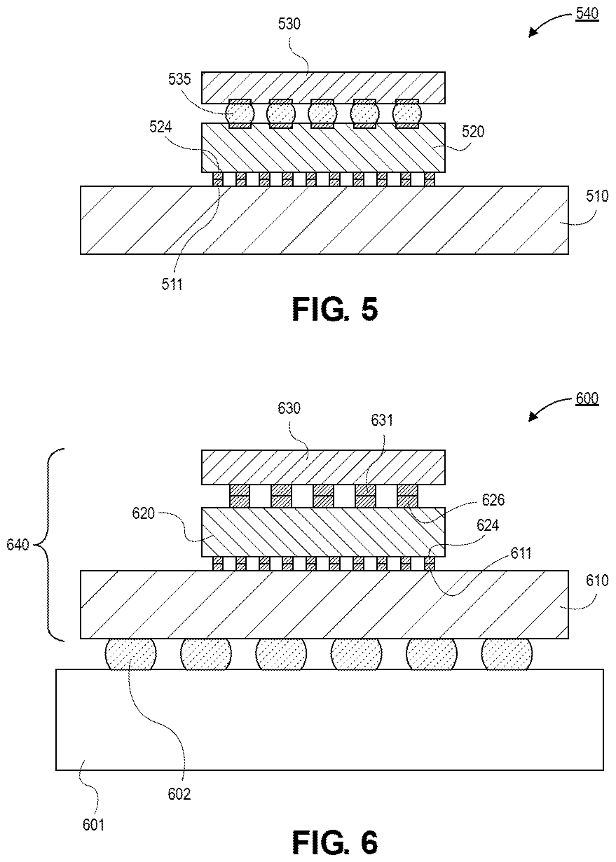

Referring now to FIG. 5, a cross-sectional illustration of a die module 540 is shown, in accordance with an embodiment. In an embodiment, the die module 540 may comprise a first die 510, a second die 530, and a third die 520 that couples the first die 510 to the second die 530. In an embodiment, the third die 520 may be a PPTD. That is, the third die 520 may provide physical pitch translation and communication protocol translation. For example, active circuitry on the third die 520 can provide serialization/deserialization, frequency modulation, and/or voltage modulation.

As opposed to embodiments described above, both sides of the third die 520 may not be bonded with hybrid bonding. For example, the interface between the third die 520 and the second die 530 may include solder balls 535. Though it is to be appreciated that any other interconnect architecture may be provided between the third die 520 and the second die 530. In an embodiment, the opposite interconnect interface between the first die 510 and the third die 520 may be a hybrid bonding interface. For example, first bumps 511 may be interdiffusion bonded to second bumps 524. Dielectric layers (not shown) around the bumps 511 and 524 may also be bonded together.

Referring now to FIG. 6, a cross-sectional illustration of an electronic package 600 is shown, in accordance with an embodiment. In an embodiment, the electronic package 600 comprises a package substrate 601 that is coupled to a die module 640 by interconnects 602. In the illustrated embodiment, the die module 640 is similar to the die module 240 in FIG. 2A. However, it is to be appreciated that the die module 640 may be similar to any of the die modules described in greater detail herein.

In the particular embodiment shown in FIG. 6, the die module 640 comprises a first die 610, a second die 630, and a third die 620. The third die 620 is coupled to the bumps 611 on the first die 610 by first bumps 624, and the third die 620 is coupled to the bumps 631 on the second die 630 by second bumps 626. The first bumps 624 may have a different pitch than the second bumps 626. In addition to providing physical pitch translation, the third die 620 may be an active die that provides communication protocol translation. For example, active circuitry on the third die 620 can provide serialization/deserialization, frequency modulation, and/or voltage modulation.

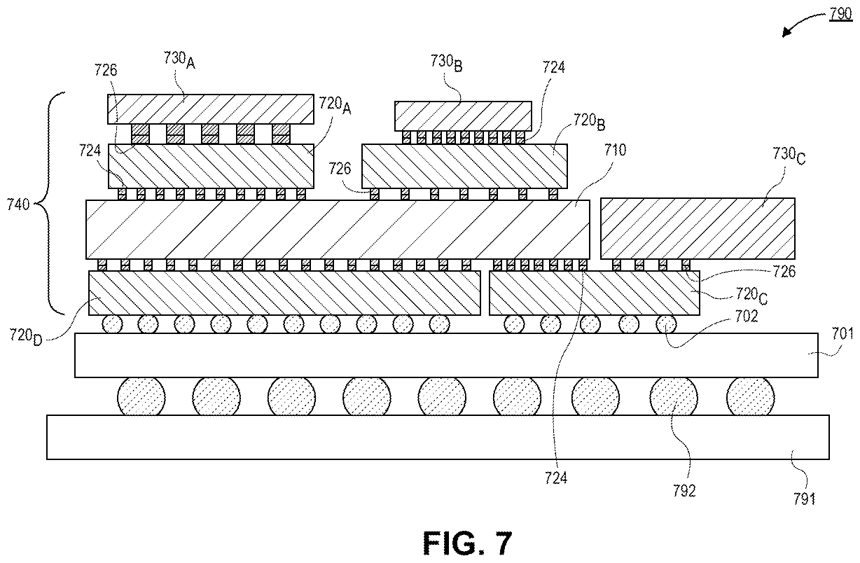

Referring now to FIG. 7, a cross-sectional illustration of an electronic system 790 is shown, in accordance with an embodiment. In an embodiment, the electronic system 790 comprises a board 791, such as a printed circuit board (PCB). In an embodiment a package substrate 701 is coupled to the board 791 by interconnects 792. The package substrate 701 may be coupled to a die module 740 by interconnects 702.

In an embodiment, the die module 740 may comprise a first die 710, a plurality of second dies 730_{A-C}, and a plurality of third dies 720_{A-D}. In an embodiment, the third dies 720 may be PPTDs, similar to embodiments described above. For example, the third dies 720 may comprise first bumps 726 and second bumps 724 with different pitches. The third dies 720 may also provide communication protocol translation. For example, active circuitry on the third dies 720 can provide serialization/deserialization, frequency modulation, and/or voltage modulation.

In an embodiment, the third dies 720_{A} and 720_{B} provide 3D coupling between dies. The third die 720_{C} provides 2.5D coupling between the first die 710 and the second die 730_{C}. The third die 720_{D} may be an interposer between the first die 710 and the package substrate 701. While a particular example of a die module 740 is shown in FIG. 7, it is to be appreciated that any die module in accordance with embodiments disclosed herein may be used in the electronic system 790.

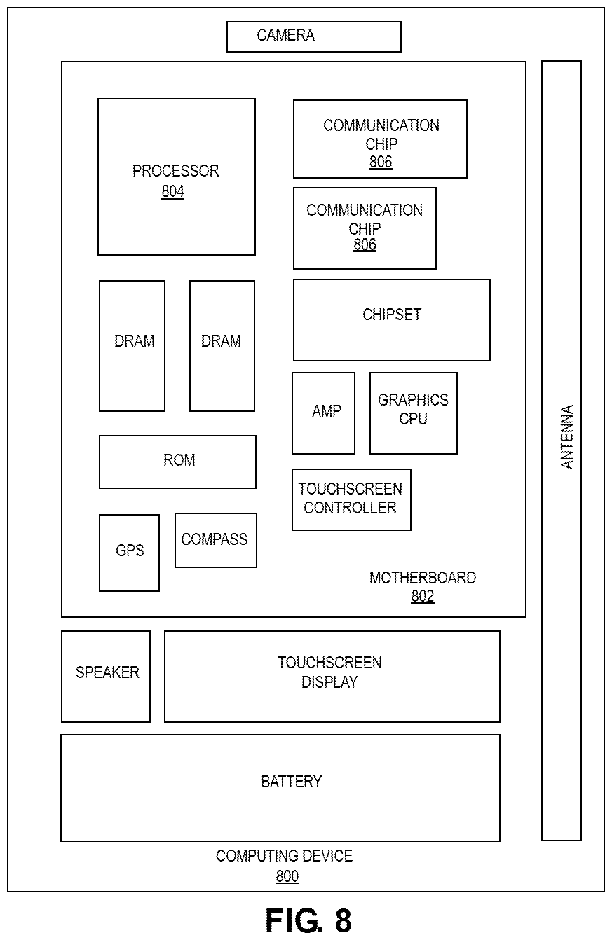

FIG. 8 illustrates a computing device 800 in accordance with one implementation of the invention. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the invention, the integrated circuit die of the processor may be part of an electronic package that comprises a PPTD to couple together dies with different bump pitches and/or communication protocols, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the invention, the integrated circuit die of the communication chip may be part of an electronic package that comprises a PPTD to couple together dies with different bump pitches and/or communication protocols, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a die, comprising: a substrate with a first surface and a second surface opposite from the first surface, wherein the substrate comprises a semiconductor material; first bumps with a first pitch on the first surface of the substrate; a first layer that surrounds the first bumps, wherein the first layer comprises a dielectric material; second bumps with a second pitch on the substrate, wherein the second pitch is greater than the first pitch; and a second layer that surrounds the second bumps, wherein the second layer comprises a dielectric material.

Example 2: the die of Example 1, wherein a number of the first bumps is greater than a number of the second bumps

Example 3: the die of Example 1 or Example 2, further comprising an active layer between the first surface and the second surface of the substrate, wherein the active layer comprises a transistor device.

Example 4: the die of Example 3, wherein the transistor device is part of active circuitry that is configured to provide serialization or deserialization of signals between the first bumps and the second bumps.

Example 5: the die of Example 3, wherein the transistor device is part of active circuitry that is configured to change a voltage or a frequency of a signal sent between the first bumps and the second bumps.

Example 6: the die of Examples 1-5, wherein the second bumps are on the second surface of the substrate.

Example 7: the die of Example 6, further comprising: through substrate vias (TSVs) through a thickness of the substrate to electrically couple first pads to second pads.

Example 8: the die of Examples 1-5, wherein the second bumps are on the first surface of the substrate.

Example 9: the die of Example 8, further comprising: conductive traces in the substrate to electrically couple first bumps to second bumps.

Example 10: the die of Examples 1-9, wherein the first pitch is approximately 20 μm or smaller.

Example 11: a die module, comprising: a first die, wherein the first die has first bumps with a first pitch; a second die coupled to the first die, wherein the second die has second bumps with the first pitch and third bumps with a second pitch that is greater than the first pitch, wherein the second bumps are bonded to the first bumps on the first die; and a third die coupled to the second die, wherein the third die has fourth bumps with the second pitch, wherein the fourth bumps are bonded to the third bumps on the second die.

Example 12: the die module of Example 11, wherein the second die is over the first die, and wherein the third die is over the second die.

Example 13: the die module of Example 11, wherein the third die is adjacent to the first die, and wherein the second die is under the first die and the third die.

Example 14: the die module of Examples 11-13, wherein the second die comprises active circuitry with a transistor device.

Example 15: the die module of Example 14, wherein the transistor device is part of circuitry configured to change a frequency of a signal sent between the first die and the third die.

Example 16: the die module of Example 14, wherein the transistor device is part of circuitry configured to change a voltage of a signal sent between the first die and the third die.

Example 17: the die module of Example 14, wherein the transistor device is part of circuitry configured to provide serialization or deserialization of signals sent between the first die and the third die.

Example 18: the die module of Examples 11-17, wherein the first pitch is approximately 20 μm or smaller.

Example 19: the die module of Examples 11-18, wherein the second bumps are bonded to the first bumps with a hybrid bonding interconnect architecture.

Example 20: the die module of Examples 11-19, wherein the third bumps are bonded to the fourth bumps with a hybrid bonding interconnect architecture.

Example 21: the die module of Examples 11-20, further comprising: a fourth die coupled to the first die; and a fifth die coupled to the fourth die.

Example 22: the die module of Example 21, wherein the fourth die comprises fifth bumps with a third pitch with the fifth bumps coupled to the first die, and sixth bumps with a fourth pitch, wherein the fifth die is coupled to the sixth bumps.

Example 23: the die module of Example 22, wherein the fourth pitch is smaller than the third pitch.

Example 24: an electronic system, comprising: a board; a package substrate coupled to the board; and a die module coupled to the package substrate, wherein the die module comprises: a first die, wherein the first die has first bumps with a first pitch; a second die coupled to the first die, wherein the second die has second bumps with the first pitch and third bumps with a second pitch that is greater than the first pitch, wherein the second bumps are bonded to the first bumps on the first die; and a third die coupled to the second die, wherein the third die has fourth bumps with the second pitch, wherein the fourth bumps are bonded to the third bumps on the second die.

Example 25: the electronic system of Example 24, wherein the second die is over the first die and the third die is over the second die, or wherein the third die is adjacent to the first die and the second die is under the first die and the third die.

What is claimed is:

1. A die, comprising:
a substrate with a first surface and a second surface opposite from the first surface, wherein the substrate comprises a semiconductor material;
first bumps with a first pitch on the first surface of the substrate;
a first layer that surrounds the first bumps, wherein the first layer comprises a dielectric material;
second bumps with a second pitch on the substrate, wherein the second pitch is greater than the first pitch; and
a second layer that surrounds the second bumps, wherein the second layer comprises a dielectric material.

2. The die of claim 1, wherein a number of the first bumps is greater than a number of the second bumps.

3. The die of claim 1, further comprising an active layer between the first surface and the second surface of the substrate, wherein the active layer comprises a transistor device.

4. The die of claim 3, wherein the transistor device is part of active circuitry that is configured to provide serialization or deserialization of signals between the first bumps and the second bumps.

5. The die of claim 3, wherein the transistor device is part of active circuitry that is configured to change a voltage or a frequency of a signal sent between the first bumps and the second bumps.

6. The die of claim 1, wherein the second bumps are on the second surface of the substrate.

7. The die of claim 6, further comprising:
through substrate vias (TSVs) through a thickness of the substrate to electrically couple first pads to second pads.

8. The die of claim 1, wherein the second bumps are on the first surface of the substrate.

9. The die of claim 8, further comprising:
conductive traces in the substrate to electrically couple first bumps to second bumps.

10. The die of claim 1, wherein the first pitch is approximately 20 μm or smaller.

11. A die module, comprising:
a first die, wherein the first die has first bumps with a first pitch;
a second die coupled to the first die, wherein the second die has second bumps with the first pitch and third bumps with a second pitch that is greater than the first pitch, wherein the second bumps are bonded to the first bumps on the first die; and
a third die coupled to the second die, wherein the third die has fourth bumps with the second pitch, wherein the fourth bumps are bonded to the third bumps on the second die.

12. The die module of claim 11, wherein the second die is over the first die, and wherein the third die is over the second die.

13. The die module of claim 11, wherein the third die is adjacent to the first die, and wherein the second die is under the first die and the third die.

14. The die module of claim 11, wherein the second die comprises active circuitry with a transistor device.

15. The die module of claim 14, wherein the transistor device is part of circuitry configured to change a frequency of a signal sent between the first die and the third die.

16. The die module of claim 14, wherein the transistor device is part of circuitry configured to change a voltage of a signal sent between the first die and the third die.

17. The die module of claim 14, wherein the transistor device is part of circuitry configured to provide serialization or deserialization of signals sent between the first die and the third die.

18. The die module of claim 11, wherein the first pitch is approximately 20 μm or smaller.

19. The die module of claim 11, wherein the second bumps are bonded to the first bumps with a hybrid bonding interconnect architecture.

20. The die module of claim 11, wherein the third bumps are bonded to the fourth bumps with a hybrid bonding interconnect architecture.

21. The die module of claim 11, further comprising:
a fourth die coupled to the first die; and
a fifth die coupled to the fourth die.

22. The die module of claim 21, wherein the fourth die comprises fifth bumps with a third pitch with the fifth bumps coupled to the first die, and sixth bumps with a fourth pitch, wherein the fifth die is coupled to the sixth bumps.

23. The die module of claim 22, wherein the fourth pitch is smaller than the third pitch.

24. An electronic system, comprising:
a board;
a package substrate coupled to the board; and
a die module coupled to the package substrate, wherein the die module comprises:
a first die, wherein the first die has first bumps with a first pitch;
a second die coupled to the first die, wherein the second die has second bumps with the first pitch and third bumps with a second pitch that is greater than the first pitch, wherein the second bumps are bonded to the first bumps on the first die; and
a third die coupled to the second die, wherein the third die has fourth bumps with the second pitch, wherein the fourth bumps are bonded to the third bumps on the second die.

25. The electronic system of claim 24, wherein the second die is over the first die and the third die is over the second die, or wherein the third die is adjacent to the first die and the second die is under the first die and the third die.
